(19) United States
(12) Patent Application Publication
(10) Pub. No.: US 2008/0043563 A1
(43) Pub. Date: Feb. 21, 2008

(54) FLEXIBLY CONTROLLING THE TRANSFER OF DATA BETWEEN INPUT/OUTPUT DEVICES AND MEMORY

(75) Inventors: Frank W. Brice, Hurley, NY (US); Robert J. Bullions, Poughkeepsie, NY (US); Daniel F. Casper, Poughkeepsie, NY (US); Joseph C. Elliot, North Creek, NY (US); John R. Flanagan, Poughkeepsie, NY (US); Mark P. Gardiner, Delmar, NY (US); Catherine C. Huang, Poughkeepsie, NY (US); Gustav E. Sittmann, Webster Groves, MO (US)

Correspondence Address: HESLIN ROTHENBERG FARLEY & MESITI P.C., 5 COLUMBIA CIRCLE, ALBANY, NY, 12203, US

(73) Assignee: INTERNATIONAL BUSINESS MACHINES CORPORATION, Armonk, NY (US)

(21) Appl. No.: 11/464,613

(22) Filed: Aug. 15, 2006

(51) Int. Cl. G11C 8/00

(52) U.S. Cl. 365/230.03

(57) ABSTRACT

Data transfer between input/output devices and memory is controlled. Data transfer begins under the control of one control block, and control of the data transfer is passed from the one control block to another control block, in response to transferring an amount of data specified in the one control block. The passing of control occurs independent of a memory boundary, providing flexibility in controlling the data transfer. Each control block includes fields that control and facilitate the data transfer.

### TECHNICAL FIELD

This invention relates, in general, to input/output processing, and in particular, to controlling the transfer of data between input/output devices and memory of a processing environment.

### BACKGROUND OF THE INVENTION

Input/output (I/O) operations are used to transfer data between memory and input/output devices. Specifically, data is written from memory to one or more input/output devices, and data is read from one or more input/output devices to memory by executing input/output operations.

To facilitate processing of input/output operations in some environments, channel command words are used. A channel command word specifies the command to be executed, and for commands initiating certain I/O operations, it designates the memory area associated with the operation, the action to be taken whenever transfer to or from the area is completed, and other options.

Channel command words include an address that directly addresses main memory or designates the address of a contiguous list of addresses to provide indirect addressing. The contiguous list of addresses, referred to as indirect data address words (IDAWs), are used to control the transfer of data that spans noncontiguous 2 KB or 4 KB blocks of memory. Specifically, control is passed to successive IDAWs in the list, when a program selected 2 KB or 4 KB boundary is reached. This transfer continues until a total amount of data specified by the channel command word has been transferred. Since the trigger to transfer control from one IDAW to the next is the program specified memory boundary of 2 KB or 4 KB, the memory location specified by the IDAW terminates on the program specified 2 KB or 4 KB boundary.

### SUMMARY OF THE INVENTION

Based on the foregoing, a need exists for more flexible control in input/output processing. For example, a need exists for a capability that enables control of the data transfer to be passed on a boundary other than a program specified 2 KB or 4 KB boundary. Further, a need exists for a capability that enables the blocks of memory to be transferred to begin and end on any boundary and/or to be greater than 4 KB. A yet further need exists for a capability to transfer the data uninterrupted by handshaking overhead between a channel and a control unit. Another need exists for a capability that validates the amount of data transferred. Other control options are also needed.

The shortcomings of the prior art are overcome and additional advantages are provided through the provision of a method of controlling data transfers of a processing environment. The method includes, for instance, commencing a data transfer at a memory address specified in one control block; and passing control of the data transfer to another control block, in response to transferring an amount of data specified in the one control block independent of a specific memory boundary.

In one embodiment, the one control block and the another control block are modified indirect data address words.

As another aspect of the present invention, a channel program is provided. The channel program includes, for instance, a channel command word specifying a list of a plurality of modified indirect data address words usable in transferring data, wherein a modified indirect data address word includes a memory address and a count field, and wherein data transfer begins at the memory address of one modified indirect data address word in the list and control of the data transfer passes to another modified indirect data address word in the list, in response to an amount of data specified in the count field of the one modified indirect data address word being transferred independent of a memory boundary.

System and computer program products corresponding to the above-summarized method are also described and claimed herein.

Additional features and advantages are realized through the techniques of the present invention. Other embodiments and aspects of the invention are described in detail herein and are considered a part of the claimed invention.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a processing environment incorporating and using one or more aspects of the present invention;

FIG. 2 depicts one example of logic associated with input/output processing, in accordance with an aspect of the present invention;

FIG. 3 depicts one embodiment of logic associated with using modified indirect data addressing words to control the transfer of data, in accordance with an aspect of the present invention; and

FIG. 4 depicts one embodiment of a computer program product incorporating one or more aspects of the present invention.

### BEST MODE FOR CARRYING OUT THE INVENTION

In accordance with an aspect of the present invention, data is transferred between input/output (I/O) devices and memory (e.g., noncontiguous (i.e., not physically contiguous) main storage, expanded storage, main memory, random access memory, or any other storage directly accessible by the central processing unit) irrespective of memory boundaries. For instance, the data need not be transferred on 2 KB or 4 KB byte boundaries. Instead, modified indirect data addressing is employed enabling data to be transferred under control of control blocks, referred to herein as modified indirect data address words (MIDAWs). Control is passed from one MIDAW to another MIDAW, in response to the amount of data specified for transfer in the one MIDAW, and assuming there is more data to transfer. The passing of control occurs independent of a memory boundary (e.g., 2 KB, 4 KB) providing flexibility in controlling data transfers.

This flexible data transfer control is usable in a number of environments, including, but not limited to, processing environments having input/output subsystems, such as channel subsystems, offered by International Business Machines Corporation, Armonk, N.Y.

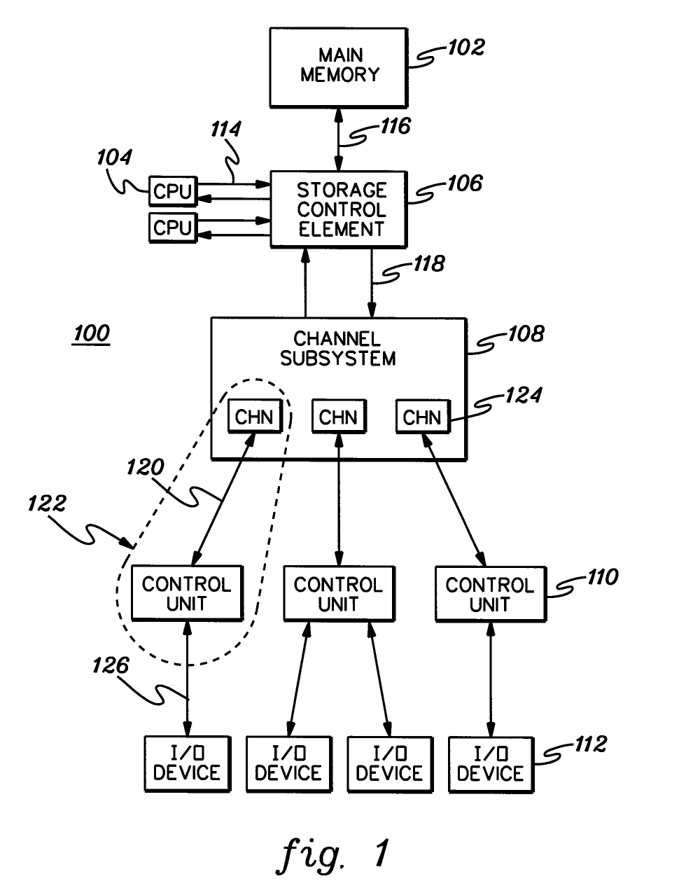

One example of a processing environment incorporating and using one or more aspects of the present invention is described with reference to FIG. 1. Processing environment 100 includes, for instance, a main memory 102, one or more central processing units (CPU) 104, a storage control element 106, a channel subsystem 108, one or more control units 110 and one or more input/output (I/O) devices 112, each of which is described below.

Main memory 102 stores data and programs, which are input from input devices 112. Main memory 102 is directly addressable and provides for high-speed processing of data by central processing units 104 and channel subsystem 108. In one example, main memory 102 includes a customer area and a system area (not shown).

Central processing unit 104 is the controlling center of environment 100. It contains the sequencing and processing facilities for instruction execution, interruption action, timing functions, initial program loading, and other machine-related functions. Central processing unit 104 is coupled to storage control element 106 via a connection 114, such as a bidirectional or unidirectional bus.

Storage control element 106 is coupled to main memory 102 via a connection 116, such as a bus, central processing units 104 via connection 114 and channel subsystem 108 via a connection 118, e.g., a double word bus. Storage control element 106 controls, for example, the queuing and execution of requests made by CPU 104 and channel subsystem 108.

Channel subsystem 108 is coupled to storage control element 106, as described above, and to each of the control units via a connection 120, such as a serial link. Channel subsystem 108 directs the flow of information between input/output devices 112 and main memory 102. It relieves the central processing units of the task of communicating directly with the input/output devices and permits data processing to proceed concurrently with input/output processing. The channel subsystem uses one or more channel paths 122 as the communication links in managing the flow of information to or from input/output devices 112. As a part of the input/output processing, channel subsystem 108 also performs the path-management functions of testing for channel path availability, selecting an available channel path and initiating execution of the operation with the input/output devices.

Each channel path 122 includes a channel 124 (channels are located within the channel subsystem, in one example, as shown in FIG. 1), one or more control units 110 and one or more connections 120. In another example, it is also possible to have one or more dynamic switches as part of the channel path. A dynamic switch is coupled to a channel and a control unit and provides the capability of physically interconnecting any two links that are attached to the switch.

Also located within channel subsystem 108 are subchannels (not shown). One subchannel is provided for and dedicated to each input/output device accessible to a program through the channel subsystem. A subchannel (e.g., a data structure, such as a table) provides the logical appearance of a device to the program. Each subchannel provides information concerning the associated input/output device 112 and its attachment to channel subsystem 108. The subchannel also provides information concerning input/output operations and other functions involving the associated input/output device. The subchannel is the means by which channel subsystem 108 provides information about associated input/output devices 112 to central processing units 104, which obtain this information by executing input/output instructions.

Channel subsystem 108 is coupled to one or more control units 110. Each control unit provides the logic to operate and control one or more input/output devices and adapts, through the use of common facilities, the characteristics of each input/output device to the link interface provided by the channel. The common facilities provide for the execution of input/output operations, indications concerning the status of the input/output device and control unit, control of the timing of data transfer over the channel path and certain levels of input/output device control.

Each control unit 110 is attached via a connection 126 (e.g., a bus) to one or more input/output devices 112. Input/output devices 112 receive information or store information in main memory 102 and/or other memory. Examples of input/output devices include card readers and punches, magnetic tape units, direct access storage devices, displays, keyboards, printers, pointing devices, teleprocessing devices, communication controllers and sensor based equipment, to name a few.

Input/output operations are initiated with device 112 by executing input/output instructions that designate the subchannel associated with the device. In one embodiment, input/output operations are initiated and controlled by, for instance, a START SUBCHANNEL instruction, which employs channel command words. The START SUBCHANNEL instruction is executed by central processing unit 104 and is part of the central processing unit program that supervises the flow of requests for input/output operations from other programs that manage or process the input/output data.

When a START SUBCHANNEL instruction is executed, parameters are passed to the target subchannel requesting that channel subsystem 108 perform a start function with the input/output device associated with the subchannel. The channel subsystem performs the start function by using information at the subchannel, including the information passed during the execution of the START SUBCHANNEL instruction, to find an accessible channel path to the device. Once a device is selected, execution of an input/output operation is accomplished by the decoding and executing of a channel command word by channel subsystem 108 and input/output device 112. The channel command word specifies the command to be executed, and one or more channel command words arranged for sequential execution form a channel program. Both instructions and channel command words are fetched from main memory 102, as one example.

The START SUBCHANNEL instruction, as well as channels, control units and channel command words are described in detail in “IBM®z/Architecture Principles of Operation,” Publication No. SA22-7832-04, 5^{th} Edition, September 2005, which is hereby incorporated herein by reference in its entirety. One or more of these components are also described in U.S. Pat. No. 5,461,721 entitled “System For Transferring Data Between I/O Devices And Main Or Expanded Storage Under Dynamic Control Of Independent Indirect Address Words (IDAWS),” Cormier et al., issued Oct. 24, 1995, and U.S. Pat. No. 5,526,484 entitled “Method And System For Pipelining The Processing Of Channel Command Words,” Casper et al., issued Jun. 11, 1996, each of which is hereby incorporated herein by reference in its entirety. IBM is a registered trademark of International Business Machines Corporation, Armonk, N.Y., USA. Other names used herein may be registered trademarks, trademarks or product names of International Business Machines Corporation or other companies.

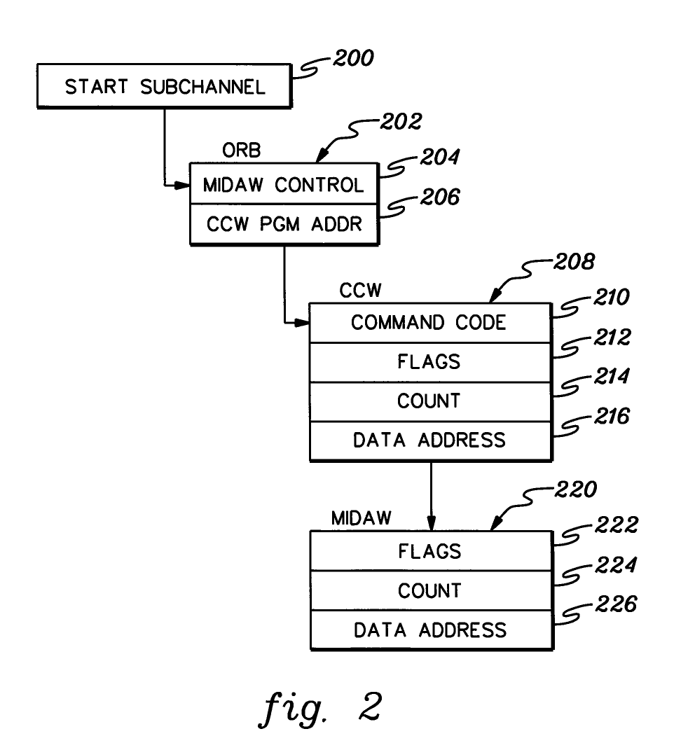

Further details related to processing an I/O request to transfer data are described with reference to FIG. 2. As previously mentioned, an I/O operation is initiated by executing a START SUBCHANNEL instruction (200). The START SUBCHANNEL instruction is initiated by a central processor and has one or more fields, including an address in memory (e.g., main memory) of an operation request block (ORB 202). ORB 202 includes a control 204 designating whether modified indirect addressing is to be employed, in accordance with an aspect of the present invention, and a channel command word (CCW) program address 206, which locates the first CCW 208 of a channel program to be executed. When control 204 is set to, for instance, 1, it specifies that the channel program may include CCWs that specify MIDAW lists, which are described in further detail below.

In response to executing the START SUBCHANNEL instruction, execution of the channel program commences. In particular, the first CCW of the program is processed. The CCW has a number of fields that control processing. These fields include, for instance, a command code 210 that specifies the operation to be performed; a plurality of flags 212 used to control the I/O operation; for commands that specify the transfer of data, a count field 214 that specifies the number of bytes in the storage area designated by the CCW to be transferred; and a data address 216 that points to a location in main memory that includes data, when indirect addressing is not employed, or in this case, when modified indirect data addressing is employed, to a list (e.g., contiguous list) of modified indirect data address words (MIDAWs) to be processed.

There are various I/O operations that can be performed, including, but not limited to, write, read, read backward, control and sense operations. With the write, read, control and sense operations, memory locations are used in ascending order of addresses. As information is transferred to or from memory, the address from the address field is incremented, and the count from the count field is decremented. The read backward operation places data in memory in a descending order of addresses, and both the count and the address are decremented. When the count reaches zero, the memory area defined by the CCW is exhausted.

In accordance with an aspect of the present invention, modified indirect data addressing (MIDA) is employed. MIDA permits a single channel command word to control the transfer of up to, for instance, 65,535 bytes of data that span noncontiguous blocks in main memory (or other memory, in another embodiment). Each block of memory to be transferred may be specified on any boundary and be of any length. Modified indirect data addressing is controlled by a flag in the ORB and specified by a flag in the CCW which, when both are set, indicate that the CCW data address is not used to directly address data, but instead, points to a contiguous list of one or more modified indirect data address words (MIDAWs). The number of MIDAWs in the list depends on the count in the CCW in that the total of all MIDAW counts is to equal the CCW count. There are to be enough MIDAWs to transfer the amount of data specified in the CCW count field.

Each MIDAW 220 is created by an operating system or device driver, as examples, and has a plurality of fields, including, for instance:
Flags 222: The flags field includes a plurality of flags, such as:
   A last MIDAW flag, which, when set, specifies that this MIDAW is the last in the contiguous list of MIDAWs;
   A skip flag, which when set, specifies the suppression of transfer of information to memory during a read, read backward, sense ID, or sense operation, thus specifying that skipping is in effect. When the operation is not read, read backward, sense ID, or sense, this flag is ignored and skipping is not in effect; and
   A data transfer interruption control flag that, when set, specifies that a program check be recognized when the device attempts to transfer data.
Count 225: The count field of the MIDAW specifies the number of bytes in the memory area designated by the data address field. When skipping is in effect, the count value may be in the range of 1-65,535, as one example. When the count value causes the total data transfer count to exceed that specified in the CCW count field, a program-check condition is recognized.
Data Address 226: This field of the MIDAW designates the address of a location in main memory, as an example, which is the first byte of information to be transferred, when the MIDAW is used for data transfer. If the count field specifies zero, this field is not checked.

When modified indirect data addressing is specified, the data address field of the CCW designates the location of the first MIDAW to be used for data transfer for the CCW command. Additional MIDAWs, if needed for completing the data transfer for the CCW, are fetched from successive locations in memory. The number of MIDAWs used for a CCW is determined by the count field of the CCW in relation to the count fields in the list of MIDAWs designated by the CCW.

The total number of bytes that can be transferred or skipped or both by a single MIDAW list is limited by the CCW count field. The sum of the count fields in all of the MIDAWs in the list designated by the CCW should equal the value in the count field of the CCW.

The MIDAW designated by the CCW can designate any location within memory. When the MIDAW skip flag is zero and the CCW specifies a read, write, control, sense ID, or sense command, data is transferred to or from successively higher memory locations until the number of bytes specified by the MIDAW count field have been transferred. When the MIDAW skip flag is zero and the CCW specifies a read backwards command, data is transferred to successively lower memory locations until the number of bytes specified by the MIDAW count field have been transferred. When the MIDAW skip flag is one and CCW specifies a read, control, sense ID, or sense command, skipping occurs to successively higher memory locations until the number of bytes specified by the MIDAW count field have been skipped. When the MIDAW skip flag is one and the CCW specifies a read backwards command, skipping occurs to successively lower memory locations until the number of bytes specified by the MIDAW count field have been skipped.

When the specified number of bytes have been transferred or skipped and a subsequent MIDAW is specified, the control of data transfer is then passed to the next MIDAW in the list. Like the MIDAW designated by the CCW, subsequent MIDAWs may designate any location and any length.

Although one MIDAW and one CCW are depicted in FIG. 2, a CCW may be associated with a list of MIDAWs, and the ORB may point to one CCW of a plurality of CCWs to be processed. Each CCW of the plurality of CCWs may or may not indicate one or more MIDAWs.

MIDAWs pertaining to the current CCW or a prefetched (fetched in advance of use) CCW may be prefetched. The number of MIDAWs that can be prefetched is not to exceed that required to satisfy the count in the CCW that designates the MIDAWs, in one embodiment. Any MIDAWs that are prefetched for a CCW and do not receive control over the I/O operation are not used. The action of transferring control from one MIDAW to the next is transparent to any attached device. A MIDAW takes control of data transfer when the operative CCW takes control (for the first MIDAW in a list) or when the last byte specified by the previous MIDAW has been transferred (for all subsequent MIDAWs in a list) and the operative CCW specifies the transfer of additional data.

A MIDAW does not take control of an I/O operation, if the count in the CCW has reached zero with the transfer of the last byte of data for the previous MIDAW. Program or access errors detected in prefetched MIDAWs are not indicated to the program until the MIDAW takes control of data transfer, even if an attempt had been made to prefetch that data.

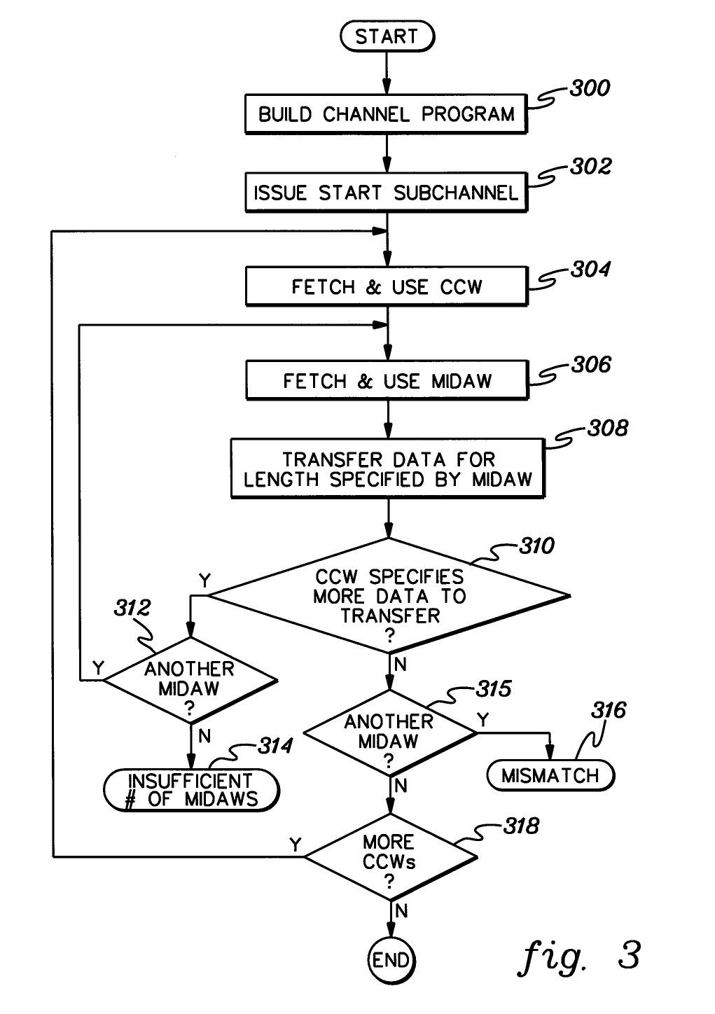

Further details regarding processing a MIDAW are described with reference to FIG. 3. Initially, a channel program is built, STEP 300. The channel program includes one or more CCWs used to control the transfer of data. Thereafter, a START SUBCHANNEL instruction is issued, STEP 302, and the first CCW is fetched and used, STEP 304. A flag in the ORB and a flag in the CCW indicates that MIDAWs are to be employed, and thus, the first MIDAW is fetched and used, STEP 306. The amount of data specified in the MIDAW, regardless of memory boundaries, is transferred, STEP 308. Thereafter, a determination is made as to whether there is more data to be transferred, INQUIRY 310. If there is more data to be transferred, as indicated by the count field in the CCW, then a determination is made as to whether there is another MIDAW to be selected, INQUIRY 312. If a flag in the current MIDAW indicates that this is the last MIDAW, then an error indicating insufficient MIDAWs to transfer the requested amount of data is indicated, STEP 314. Otherwise, another MIDAW is selected, STEP 306.

Returning to INQUIRY 310, if there is no more data to be transferred for this CCW, a further inquiry is made as to whether there is another MIDAW to be processed, INQUIRY 315. If so, a mismatch is indicated, indicating that there are more MIDAWs than there is data to be transferred, STEP 316. However, if there is not another MIDAW to be processed (or, in another embodiment, after specifying error 314 and/or error 316), a determination is made as to whether there are more CCWs to be processed, INQUIRY 318. In one example, this is determined by a flag in the current CCW. Should there be more CCWs to be executed, processing continues with STEP 304. Otherwise, processing of the channel program is complete.

Described in detail above is a technique that provides flexible control of transferring data between, for instance, I/O devices and noncontiguous memory, under control of modified indirect data address words. Modified indirect data addressing provides a more flexible and more usable technique for transferring data between a device and multiple noncontiguous blocks of memory. It permits a single CCW to control the transfer of data beginning and ending on any boundary (i.e., non-page boundaries) between a device and memory mapped to pages in a virtual address space. MIDA also permits the transfer of larger than noncontiguous 4 KB blocks of data.

One or more aspects of the present invention can be included in an article of manufacture (e.g., one or more computer program products and/or systems) having, for instance, computer usable media. The media have therein, for instance, computer readable program code means of logic (e.g., instructions, code, commands, etc.) to provide and facilitate the capabilities of the present invention. The article of manufacture can be included as a part of a computer system or sold separately.

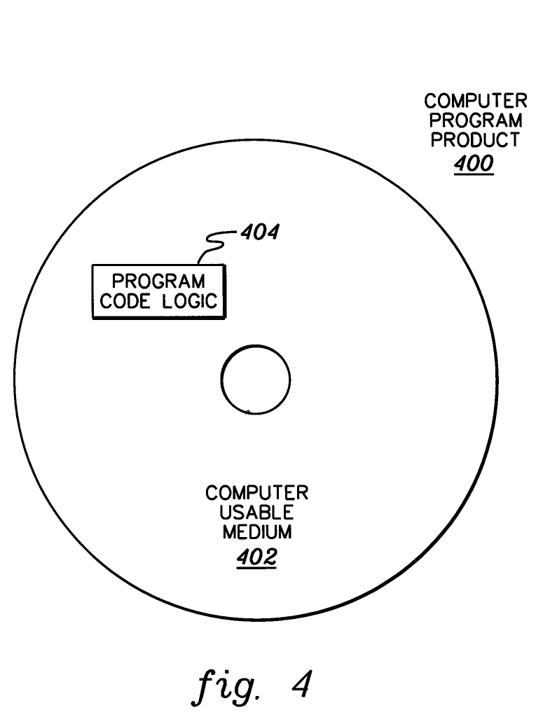

One example of an article of manufacture or a computer program product incorporating one or more aspects of the present invention is described with reference to FIG. 4. A computer program product 400 includes, for instance, one or more computer usable media 402 to store computer readable program code means or logic 404 thereon to provide and facilitate one or more aspects of the present invention. The medium can be an electronic, magnetic, optical, electromagnetic, infrared, or semiconductor system (or apparatus or device) or a propagation medium. Examples of a computer readable medium include a semiconductor or solid state memory, magnetic tape, a removable computer diskette, a random access memory (RAM), a read-only memory (ROM), a rigid magnetic disk and an optical disk. Examples of optical disks include compact disk-read only memory (CD-ROM), compact disk-read/write (CD-R/W) and DVD.

A sequence of program instructions or a logical assembly of one or more interrelated modules defined by one or more computer readable program code means or logic direct the performance of one or more aspects of the present invention.

Advantageously, a scatter/gather technique for transferring data is provided. A capability of transferring data is provided in which the amount of data to be transferred is independent of a specific memory boundary. This technique provides relief to the program selectable maximum 2 KB/4 KB block size limitation imposed by other indirect data addressing techniques. Further, a separate transfer count is associated with each indirect data address, and control is transferred from one listed indirect data address to the next based on the count field associated with the indirect data address. Skipping on a per indirect address and associated count basis is also enabled and validation of the size of the list of indirect data addresses is provided.

Advantageously, discontiguous blocks of memory may be specified on any boundary and length (e.g., in one embodiment, up to 64 K-1) without using chained data CCWs.

Modified indirect data addressing provides a mechanism in which a program can specify a channel program that controls the transfer of data that spans noncontiguous blocks of memory that are on any boundary and of any size. Such a channel program includes, for instance, one or more channel command words whose address field is not used to address data, but is used to designate the address of a contiguous list of modified indirect data address words. The list of MIDAWs is not a list of addresses, but a list of control blocks, in which each control block (i.e., MIDAW) includes information used in processing.

Each MIDAW includes a count field that specifies the amount of data to be transferred when that MIDAW is in control. The transfer of control from one MIDAW on the list to the next is controlled by a combination of the CCW count field and the MIDAW count field. When data transfer begins, the first MIDAW on the list is used to designate where, for instance, in main memory the transfers begins. If the value of the CCW count field exceeds the value of the count field in the first MIDAW and the last MIDAW flag is zero, the next MIDAW assumes control and data transfer continues at the main memory address designated by that MIDAW. This process of passing control to successive MIDAWs in the list continues until a total amount of data specified by the CCW count field has been transferred.

Because the MIDAW includes an address field and a count field, the memory location specified by any MIDAW can begin and end on any boundary.

Further, each MIDAW includes a flag field in which there is a skip indicator. If the skip indicator is one when the MIDAW gets control during data transfer, the range of memory specified by the MIDAW is skipped and no data transfer is performed for that range.

The MIDAW flag field also includes an indicator that the MIDAW is the last MIDAW in the list. Thus, if the CCW count field specifies the transfer of control to a subsequent MIDAW when this indicator is one, there is a mismatch between CCW and the MIDAW list. Similarly, if the total amount of data specified by the CCW has been transferred and the MIDAW currently in control has its flag set to zero, there is also a mismatch between the CCW and MIDAW list. In either case, the program can be informed via a channel program check to indicate the error.

Although various embodiments are described above, these are only examples. Processing environments other than those described herein, including others that use I/O subsystems, other than channel subsystems, can incorporate and use one or more aspects of the present invention. Further, although various control blocks have been shown, the location of the information within those control blocks may be other than shown herein. Further, each control block may include additional, less or different information than described herein. For instance, there may be additional, fewer and/or different fields, including fields that may include additional, fewer and/or different flags. Further, there may be additional, fewer and/or different field sizes. Yet further, although main memory is mentioned or described in various portions of the embodiment, one or more aspects of the present invention may be applicable to other memory.

In yet further embodiments, it is possible to implement certain restrictions, if desired. For example, a restriction may be implemented that a MIDAW list may not be specified to cross a particular boundary, such as a 4 KB byte boundary. This would limit the maximum MIDAW list size to 256 MIDAWs. Further, a single MIDAW may specify a data count that may not exceed a particular boundary, such as a 4 KB boundary, and/or is not to specify the transfer of data across a 4 KB byte boundary. In yet further examples, the skip flag need not only apply to read operations. Any other changes and/or enhancements may be made without departing from the spirit of the present invention.

Moreover, an environment may include an emulator (e.g., software or other emulation mechanisms), in which a particular architecture or subset thereof is emulated. In such an environment, one or more emulation functions of the emulator can implement one or more aspects of the present invention, even though a computer executing the emulator may have a different architecture than the capabilities being emulated. As one example, in emulation mode, the specific instruction or operation being emulated is decoded, and an appropriate emulation function is built to implement the individual instruction or operation.

In an emulation environment, a host computer includes, for instance, a memory to store instructions and data; an instruction fetch unit to fetch instructions from memory and to optionally, provide local buffering for the fetched instruction; an instruction decode unit to receive the instruction fetch unit and to determine the type of instructions that have been fetched; and an instruction execution unit to execute the instructions. Execution may include loading data into a register for memory; storing data back to memory from a register; or performing some type of arithmetic or logical operation, as determined by the decode unit. In one example, each unit is implemented in software. For instance, the operations being performed by the units are implemented as one or more subroutines within emulator software.

Further, a data processing system suitable for storing and/or executing program code is usable that includes at least one processor coupled directly or indirectly to memory elements through a system bus. The memory elements include, for instance, local memory employed during actual execution of the program code, bulk storage, and cache memory which provide temporary storage of at least some program code in order to reduce the number of times code must be retrieved from bulk storage during execution.

Input/Output or I/O devices (including, but not limited to, keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modems, and Ethernet cards are just a few of the available types of network adapters.

The capabilities of one or more aspects of the present invention can be implemented in software, firmware, hardware, or some combination thereof. At least one program storage device readable by a machine embodying at least one program of instructions executable by the machine to perform the capabilities of the present invention can be provided.

The flow diagrams depicted herein are just examples. There may be many variations to these diagrams or the steps (or operations) described therein without departing from the spirit of the invention. For instance, the steps may be performed in a differing order, or steps may be added, deleted, or modified. All of these variations are considered a part of the claimed invention.

Although preferred embodiments have been depicted and described in detail there, it will be apparent to those skilled in the relevant art that various modifications, additions, substitutions and the like can be made without departing from the spirit of the invention and these are therefore considered to be within the scope of the invention as defined in the following claims.

What is claimed is:

1. A method of controlling data transfers of a processing environment, said method comprising:
commencing a data transfer at a memory address specified in one control block; and
passing control of the data transfer to another control block, in response to transferring an amount of data specified in the one control block independent of a specific memory boundary.

2. The method of claim 1, wherein said one control block comprises a count indicating the amount of data to be transferred, said count being independent of a memory boundary.

3. The method of claim 1, further comprising determining whether additional data is to be transferred, and wherein the passing is in further response to the determining indicating additional data is to be transferred.

4. The method of claim 3, wherein said determining comprises comparing a count of the one control block with a count of a command word associated with the one control block to determine whether additional data is to be transferred.

5. The method of claim 1, wherein the another control block includes an address in memory to be used in the transfer, said address designating a block of memory not on a specific memory boundary and discontiguous to a block of memory designated by the one control block.

6. The method of claim 1, further comprising determining, in response to the another control block receiving control, whether data transfer for a range of memory specified by the another control block is to be skipped, said determining employing an indicator of the another control block.

7. The method of claim 1, wherein the one control block and the another control block are included within a list of control blocks, and further comprising verifying that the list of control blocks to be used in the data transfer includes enough control blocks to transfer a specified amount of data.

8. The method of claim 7, wherein the specified amount of data is included in a command word associated with the list of control blocks, and wherein the verifying employs an indicator of at least one control block of the list of control blocks.

9. The method of claim 1, wherein the one control block and the another control block are included in a list of control blocks, said list of control blocks including at least the one control block and the another control block, and said list of control blocks being specified by a command word of a program to facilitate the data transfer, the data transfer being between one or more input/output devices and noncontiguous memory.

10. The method of claim 1, wherein the data transfer proceeds uninterrupted by handshaking overhead between a channel and a control unit of the processing environment.

11. A system of controlling data transfers of a processing environment, said system comprising:
one control block having a memory address designating a location at which data transfer is to begin; and
another control block to receive control of the data transfer from the one control block, in response to an amount of data specified in the one control block being transferred, independent of a memory boundary.

12. The system of claim 11, wherein said one control block comprises a count to be compared with a count of a command word associated with the one control block to determine whether additional data is to be transferred.

13. The system of claim 11, wherein the another control block includes an address in memory to be used in the transfer, said address designating a block of memory not on a specific memory boundary and discontiguous to a block of memory designated by the one control block.

14. The system of claim 11, wherein the another control block includes an indicator used, in response to the another control block receiving control, to determine whether data transfer for a range of memory specified by the another control block is to be skipped.

15. The system of claim 11, wherein the one control block and the another control block are included within a list of control blocks, and wherein at least one control block of the list of control blocks includes an indicator used to verify that the list of control blocks to be used in the data transfer includes enough control blocks to transfer a specified amount of data.

16. An article of manufacture comprising:
at least one computer usable medium having computer readable program code logic to control data transfers of a processing environment, the computer readable program code logic comprising:
commence logic to commence a data transfer at a memory address specified in one control block; and
pass logic to pass control of the data transfer to another control block, in response to transferring an amount of data specified in the one control block independent of a memory boundary.

17. The article of manufacture of claim 16, further comprising logic to determine whether additional data is to be transferred, and wherein the passing is in further response to the determining indicating additional data is to be transferred.

18. The article of manufacture of claim 16, wherein the another control block includes an address in memory to be used in the transfer, said address designating a block of memory not on a specific memory boundary and discontiguous to a block of memory designated by the one control block.

19. The article of manufacture of claim 16, further comprising logic to determine, in response to the another control block receiving control, whether data transfer for a range of memory specified by the another control block is to be skipped, said logic employing an indicator of the another control block.

20. A channel program comprising:
a channel command word specifying a list of a plurality of modified indirect data address words usable in transferring data, wherein a modified indirect data address word comprises a memory address and a count field, and wherein data transfer begins at the memory address of one modified indirect data address word in the list and control of the data transfer passes to another modified indirect data address word in the list, in response to an amount of data specified in the count field of the one modified indirect data address word being transferred independent of a memory boundary.
